(19) United States
(12) Patent Application Publication
(10) Pub. No.: US 2006/0139061 A1
(43) Pub. Date: Jun. 29, 2006

(54) Protected set dominant latch

(76) Inventors: Steve M. Curtis, Buda, TX (US); Grant W. McFarland, Hillsboro, OR (US); Brian F. Flanagan, Buda, TX (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/023,751

(22) Filed: Dec. 27, 2004

(51) Int. Cl. H03K 19/096

(52) U.S. Cl. 326/95

(57) ABSTRACT

In some embodiments, a set dominant latch with an input node and a state node is provided the circuit includes at least one driver gate coupled to the state node and to the input node to provide a driven output of the state node. Other embodiments are disclosed and/or otherwise claimed.

### TECHNICAL FIELD

Embodiments disclosed herein relate generally to integrated circuit (“IC”) devices and in particular to dynamic logic circuits.

### BACKGROUND

High-speed chips such as microprocessors use domino circuits to implement logic functions. (As used herein, the term “chip,” or die, refers to a piece of a material, such as a semiconductor material, that includes a circuit such as an integrated circuit or a part of an integrated circuit.) Domino circuits generally comprise multiple sections of one or more gate and/or latch stages cascaded together to form a domino chain. (Domino gates can include any suitable gate circuits including but not limited to dynamic precharge/evaluate gates and static gates.) When operated, an upstream stage in the chain is caused to evaluate, which causes the next stage to evaluate, and so on like a chain of falling dominos until an output state (or value) at the end of the chain (or chain section) is attained.

Different stages may or may not be clocked, and of those that are clocked, they may have different clock signals driving them; although each section of one or more adjacent stages will normally have at least a clocked stage in its beginning to control precharge and evaluate operations for the section. They may also have a clocked device (such as a latch) at the end of the section to store the section's evaluated state and to properly transfer it to the next section. In the past, basic latches were used for this purpose. They operated suitably but had certain cost performance drawbacks (e.g., speed, power) because data was required to get through the latch before it closed (e.g., by the end of an evaluate phase).

Set dominant latches (“SDL”s) were then developed to redress this drawback. Like a basic latch, they can capture and hold a domino state received during an evaluate phase, but they can also be set after transitioning out of an evaluate phase allowing for higher performance operation. Unfortunately, however, they can be susceptible to noise and can consume excessive clock power.

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1 is a schematic diagram of a portion of a prior art domino circuit with a set dominant latch.

FIG. 2 is a schematic diagram of a portion of a domino circuit with a protected set dominant latch according to some embodiments of the present invention.

FIG. 3 is a block diagram of a system having a processor chip with a domino circuit with a protected set dominant latch according to some embodiments of the present invention.

### DETAILED DESCRIPTION

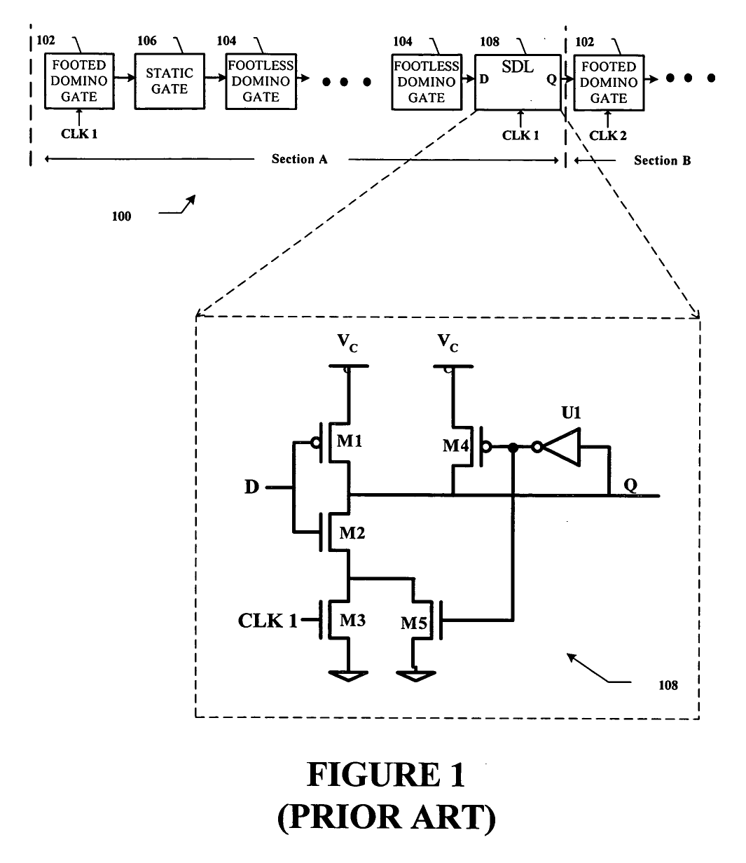

FIG. 1 shows a portion 100 of an exemplary domino chain 100 having a prior art set dominant latch (“SDL”) 108. The depicted circuit portion 100 shows domino sections (Section A and Section B) cascaded to one another. The depicted portion of Section A includes a footed domino gate 102, footless domino gates 104, static gates 106, and a set dominant latch 108. The depicted portion of Section B includes a footed domino gate 102. (A “footed domino gate” is a domino gate circuit having a clocked transistor, e.g., coupled to a ground, to controllably provide a discharge path for an evaluate phase and inhibit discharge during a precharge phase. On the other hand, a “footless domino gate” is a domino gate circuit without such a clocked transistor. Domino sections could include some or all of these gate types.)

The footed gate 102 and SDL 108 in Section A are controlled with a first clock signal (Clk 1), while the footed gate 102 in Section B is controlled with a second clock signal (Clk 2). In this depiction, the first and second clock signals (Clk 1 and Clk 2) are approximately 180 degrees out of phase from one another. The end of an evaluate phase for Section A will generally occur just prior to the beginning of an evaluate phase for Section B. Thus, when Clk 1 transitions to an evaluate phase, the footed gate 102 of Section A evaluates causing the subsequent gates in the section to evaluate until a resulting state (or value) reaches the end of the section at the SDL 108. Here, it is latched for use as the data input to the next section (Section B) at its first stage, footed gate 102. A benefit of using the SDL in this context is that even if the evaluated state reaches the SDL after Clk 1 has transitioned out of an evaluate phase, it can still “set” the SDL and be made available to Section B.

The SDL 108 comprises PMOS transistors M1, M4, NMOS transistors M2, M3, M5, and an inverter U1. (“NMOS transistor” refers to N-type metal oxide semiconductor field effect transistor. Likewise, “PMOS transistor” refers to P-type metal oxide semiconductor field effect transistor. It should be appreciated, however, that whenever the terms: “transistor”, “MOS transistor”, “NMOS transistor”, or “PMOS transistor” are used, unless otherwise expressly indicated or dictated by the nature of their use, they are being used in an exemplary manner. Other appropriate transistor types, known today or not yet developed, could be used in their place.)

Transistors M1 and M2 are configured with their gates connected together providing a data input (D) and with their drains connected together providing a state output (Q). With the source of M1 coupled to V_{cc}, and the source of M2 coupled to the drains of M3 and M5, transistors M1/M2 function like an inverter when M3 or M5 are turned on. Transistor M3 is a clocked transistor (controlled by Clk 1) turning off during a precharge phase and on for an evaluate phase. Transistor M4 serves as a keeper transistor for holding a High at the output node (Q), and transistor M5 functions as a keeper for holding the output Low. Inverter U1 provides keeper transistors M4 and M5 with an inverted version of the state output (Q) to control the keeper transistors to turn on/off at appropriate times.

In operation, the SDL functions as an inverting latch that can also be “set” during a non-evaluate phase. During an evaluate phase (M3 turned on), it latches through to its state output (Q) an inverted version of the input (D). In addition, however, during a non-evaluate phase (M3 turned off), it can be set with an active Low applied at its input (D) to latch to its output a High. During an evaluate phase (Clk 1 High), clocked transistor M3 turns on, which causes M1 and M2 to function as an inverter and apply an inverted D at the output node (Q). If the state (or value) at Q is High, keeper transistor M4 turns on to hold the output High. Conversely, if Q is Low, keeper transistor M5 turns on to hold Q Low when the SDL is not in an evaluate phase. It will hold the output Low during a precharge phase (M3 off) unless and until the SDL is “set” by a Low (or Low pulse) at the input (D). In this way, the SDL 108 properly holds the evaluated state of Section A, even if the section's evaluated value does not reach it until after it transitions out of an evaluate phase. This allows for the domino sections to be designed with higher performance capabilities. Again, however, such an SDL can have certain drawbacks due to noise susceptibility and clock power consumption.

Disclosed herein are novel protected SDLs (“PSDL”s), which can provide the performance of traditional SDLs without the same routing restrictions and clock power consumption. In some embodiments, another benefit of using a PSDL is that it can serve as a “drop-in” replacement for SDLs in existing designs.

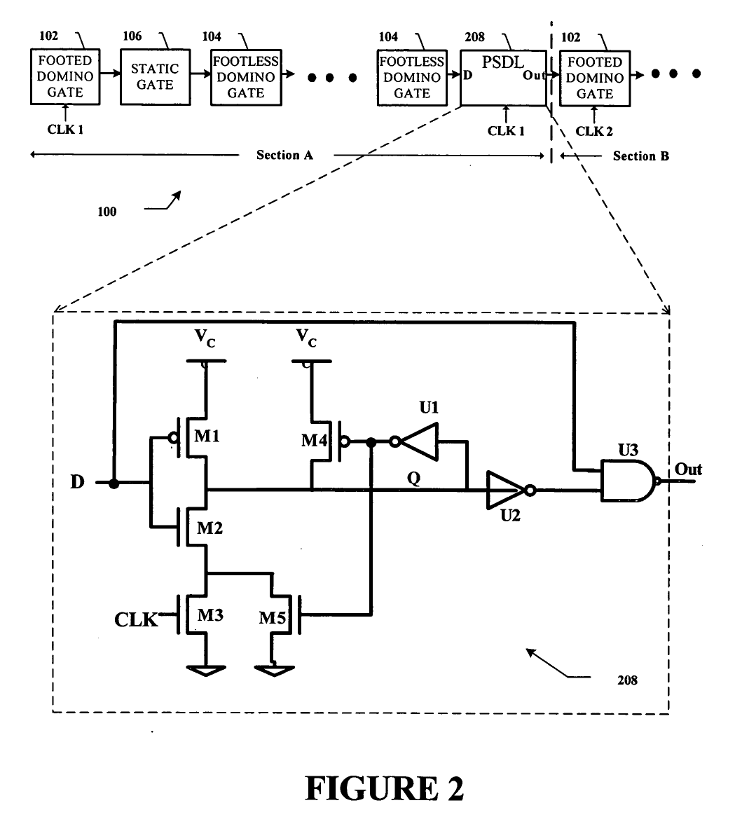

FIG. 2 shows the portion of the domino chain of FIG. 1 but with one embodiment of a PSDL 208 substituted for the SDL 108. In this embodiment, the PSDL comprises the basic SDL components of FIG. 1 with an added inverter U2 and NAND gate U3. The inverter U2 is coupled between the state node (Q) and one of the inputs of the NAND gate U3. the other NAND gate input is coupled to the input node (D). The NAND gate output (Out) serves as the functional output for the PSDL 208.

With the utilized logic, the PSDL has the same forward delay as the SDL from the viewpoint of surrounding circuitry. That is, with the input (D) coupled to one of the NAND gate inputs, the time occurring for a state change at D to be coupled through to the output (Out) is substantially (or at least can be made to be) the same as from the input (D) to the state node (Q). This makes it more convenient to use such a PSDL as a drop-in replacement for a traditional SDL. (Note that any suitable logic gate structures could be used instead of U2 and U3 for providing similar timing and functionality. Along these lines, any suitable latch circuitry, whether or not performing a logic function, that can latch a value during an evaluate phase and be set even outside of an evaluate phase, can be used to implement the SDL portion of the PSDL.)

In addition, the inverter U2 and NAND gate U3 serve as isolation drivers isolating the state node (Q) from the PSDL output (Out) and thus from coupled noise. The NAND gate U3 also serves as an output driver. Thus, the PSDL has greater routing capabilities and can drive larger loads. Note that even though two extra devices (inverter U2 and NAND gate U3) are used, the PSDL actually may take up less overall power and space than the SDL of FIG. 1 because the transistors in the SDL portion of the PSDL can be made to be smaller. In turn, with a smaller clocked transistor M3, loading on the clock can be reduced.

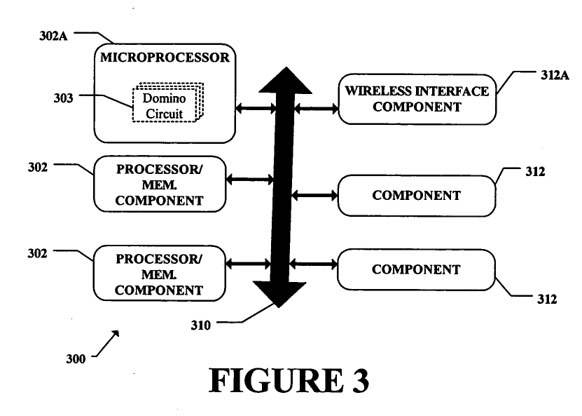

With reference to FIG. 3, one example of a system (system 300 for a computer) that may be implemented with one or more IC chips or modules (including a microprocessor chip 302A) is shown. System 300 generally comprises one or more processor/memory components 302, an interface system 310, and one or more other components 312. At least one of the one or more processor/memory components 302 is communicatively linked to at least one of the one or more other components 312 through the interface system 310, which comprises one or more interconnects and/or interconnect devices including point-to-point connections, shared bus connections, and/or combinations of the same.

A processor/memory component is a component such as a processor, controller, memory array, or combinations of the same contained in a chip or in several chips mounted to the interface system or in a module or circuit board coupled to the interface system. Included within the depicted processor/memory components is microprocessor chip 302A, which has one or more domino circuits 303 with PSDLs in accordance with embodiments of the invention, as disclosed herein. The one or more depicted other components 312 could include any component of use in a computer system such as a sound card, network card, Super I/O chip, or the like. In the depicted embodiment, the other components 312 include a wireless interface component 312A, which serves to establish a wireless link between the microprocessor 302A and another device such as a wireless network interface device or a computer. It should be noted that the system 300 could be implemented in different forms. That is, it could be implemented in a single chip module, a circuit board, or a chassis having multiple circuit boards. Similarly, it could constitute one or more complete computers or alternatively, it could constitute a component useful within a computing system.

While the inventive disclosure has been described in terms of one or more embodiments, those skilled in the art will recognize that the invention is not limited to the embodiments described, but can be practiced with modification and alteration within the spirit and scope of the appended claims. For example, while the domino circuit embodiments are primarily discussed in the context of processor chips, other types of chips (such as bus, transceiver, network, or any other chips using domino sections) could employ a domino circuit with a PSDL as discussed herein.

It should be appreciated that example sizes/models/values/ranges may have been given, although the present invention is not limited to the same. As manufacturing techniques (e.g., photolithography) mature over time, it is expected that devices of smaller size could be manufactured. With regard to description of any timing or programming signals, the terms “assertion” and “negation” are used in an intended generic sense. More particularly, such terms are used to avoid confusion when working with a mixture of “active-low” and “active-high” signals, and to represent the fact that the invention is not limited to the illustrated/described signals, but can be implemented with a total/partial reversal of any of the “active-low” and “active-high” signals by a simple change in logic. More specifically, the terms “assert” or “assertion” indicate that a signal is active independent of whether that level is represented by a high or low voltage, while the terms “negate” or “negation” indicate that a signal is inactive. In addition, well known power/ground connections to IC chips and other components may or may not be shown within the FIGS. for simplicity of illustration and discussion, and so as not to obscure the invention. Further, arrangements may be shown in block diagram form in order to avoid obscuring the invention, and also in view of the fact that specifics with respect to implementation of such block diagram arrangements are highly dependent upon the platform within which the present invention is to be implemented, i.e., such specifics should be well within purview of one skilled in the art. Where specific details (e.g., circuits) are set forth in order to describe example embodiments of the invention, it should be apparent to one skilled in the art that the invention can be practiced without, or with variation of, these specific details. The description is thus to be regarded as illustrative instead of limiting.

What is claimed is:

1. A chip, comprising:
(a) a set dominant latch circuit having an input node and a state node; and
(b) at least one driver gate coupled to the state node and the input node to provide a driven output of the state node.

2. The chip of claim 1, in which the at least one driver gate comprises a NAND gate with an input coupled to the set dominant latch circuit input.

3. The chip of claim 2, in which the at least one gate further comprises an inverter coupled between the state node and a second input of the NAND gate.

4. The chip of claim 3, in which the input of the set dominant latch is active Low for setting the set dominant latch.

5. The chip of claim 4, in which the set dominant latch provides an inverting function between its input node and the state node.

6. The chip of claim 1, in which the set dominant latch and at least one gate are part of a stage in a first domino section.

7. The chip of claim 6, in which the stage couples the first domino section to one or more downstream domino sections.

8. A chip, comprising:
(a) a latch in a domino section, the latch having an input node and a state node and being capable of latching a value during an evaluate phase and being set upon receiving an active input when out of the evaluate phase when being operated; and
(b) at least one driver gate coupled to the state node and the input node to provide a driven output of the state node.

9. The chip of claim 8, in which the at least one driver gate comprises a NAND gate with an input coupled to the latch input.

10. The chip of claim 9, in which the at least one gate further comprises an inverter coupled between the state node and a second input of the NAND gate.

11. The chip of claim 10, in which the input of the latch is active Low for setting the latch.

12. The chip of claim 11, in which the latch provides an inverting function between its input node and the state node.

13. The chip of claim 12, in which the state node goes High when the latch is set upon receiving at its input the active Low value.

14. The chip of claim 8, in which the circuit formed by the latch and at least one gate couple the domino section to one or more downstream domino sections.

15. The chip of claim 8, in which the at least one gate isolates the state node from other circuit devices.

16. A system, comprising:
(a) a microprocessor having a domino circuit comprising:
(i) a set dominant latch circuit having an input node and a state node, and
(ii) at least one driver gate coupled to the state node and the input node to provide a driven output of the state node; and
(b) a wireless interface component communicatively linked to the microprocessor.

17. The system of claim 16, in which the at least one driver gate comprises a NAND gate with an input coupled to the set dominant latch circuit input.

18. The system of claim 17, in which the at least one gate further comprises an inverter coupled between the state node and a second input of the NAND gate.

19. The system of claim 18, in which the input of the set dominant latch is active Low for setting the set dominant latch.

20. The system of claim 19, in which the set dominant latch provides an inverting function between its input node and the state node.

21. The system of claim 16, in which the set dominant latch and at least one gate are part of a stage in a first domino section.

22. The system of claim 21, in which the stage couples the first domino section to one or more downstream domino sections.
